(19) United States
(12) Patent Application Publication
(10) Pub. No.: US 2025/0157944 A1
(43) Pub. Date: May 15, 2025

(54) MULTI-GATE TOTAL IONIZING DOSE (TID) RADIATION-HARDENED DEVICE

(71) Applicant: Peking University, Beijing (CN)

(72) Inventors: Xia AN, Beijing (CN); Qiaofeng YUAN, Beijing (CN); Wei GUO, Beijing (CN); Liangchen WAN, Beijing (CN); Zihao WANG, Beijing (CN); Ru HUANG, Beijing (CN)

(21) Appl. No.: 19/021,004

(22) Filed: Jan. 14, 2025

(30) Foreign Application Priority Data
Feb. 28, 2024 (CN) 202410219466.4

(51) Int. Cl. H01L 23/552

(52) U.S. Cl. CPC H01L 23/552

(57) ABSTRACT

A multi-gate total ionizing dose (TID) radiation-hardened device includes a semiconductor substrate on which a shallow trench isolation (STI) region and a plurality of Fin structures are provided. The STI region is provided between adjacent two Fin structures. A middle portion of a section of the STI region perpendicular to a source-drain direction is hollowed out. A surface of an upper part of each Fin structure not in contact with the STI structure is provided with a gate structure across the Fin structures. A part of the Fin structures in contact with the gate structure is configured as a channel region. A lower part of each Fin structure is covered by the STI region.

### CROSS-REFERENCE TO RELATED APPLICATIONS

This application claims the benefit of priority from Chinese Patent Application No. 202410219466.4, filed on Feb. 28, 2024. The content of the aforementioned application, including any intervening amendments made thereto, is incorporated herein by reference in its entirety.

### TECHNICAL FIELD

This application relates to the semiconductor technology, and more particularly to a multi-gate total ionizing dose (TID) radiation-hardened device.

### BACKGROUND

With the rapid advancement of aerospace technology, extensive electronic devices are deployed in an environment exposed to space radiation. After exposed to the long-term irradiation from γ rays, electrons, and X-rays, semiconductor devices will suffer a total ionizing dose (TID) effect, which will impact the direct current (DC) characteristics of devices, such as increased off-state leakage current, threshold voltage drift, and transconductance variation, leading to performance degradation and even failure of integrated circuits. Consequently, extensive researches have been conducted to enhance the radiation hardness of integrated circuits. With the reduction of feature size of semiconductor devices to the nanoscale, multi-gate devices (e.g., three-dimensional Fin Field-Effect Transistor (FinFET)) have emerged as the mainstream commercial structures due to the excellent gate control ability. The continuous reduction in the feature size leads to a decrease in the thickness of gate oxide layers, where the absolute number of radiation-induced oxide-trapped charges decreases, thereby strengthening the gate oxide. Therefore, in bulk substrate-based multi-gate devices, the TID radiation-sensitive region shifts to the STI region. Particularly, the impact of radiation-induced trapped charge in the STI region will be exacerbated as the Fin width is narrowed.

### SUMMARY

An object of the present disclosure is to provide a multi-gate total ionizing dose (TID) radiation-hardened device to remedy the defects that the existing multi-gate bulk-silicon-based devices have poor radiation hardness to TID. The middle portion of the STI region's cross-section is hollowed out, and the remaining STI region wraps around the Fin strips on both sides of the STI region. Due to the reduction in the size of the oxide layer, the number of radiation-induced oxide-trapped charges decreases, making it difficult for the Sub-Fin region to invert to form a leakage path. Therefore, the increase in the radiation-induced off-state leakage current can be relieved, thereby enhancing the TID radiation hardness.

The technical solutions of the present disclosure are described as follows.

A multi-gate TID radiation-hardened device, comprising:
a semiconductor substrate;
wherein a plurality of Fin structures and a STI region are provided on the semiconductor substrate;
the STI region is provided between adjacent two of the plurality of Fin structures; and a middle portion of a section of the STI region perpendicular to a source-drain direction is configured to be hollowed out;
a surface of an upper part of each of the plurality of Fin structures not in contact with the STI region is provided with a gate structure across the plurality of Fin structures; and a region of the plurality of Fin structures in contact with the gate structure is configured as a channel region; and
a lower part of each of the plurality of Fin structures is configured to be covered by the STI region; and a source and a drain are provided at two ends of the channel region, respectively.

In an embodiment, the middle portion of the section of the STI region is configured to be partially or completely hollowed out.

In an embodiment, the middle portion of the section of the STI region is configured to be completely hollowed out to expose the semiconductor substrate.

In an embodiment, the middle portion of the section of the STI region is configured to be partially hollowed out, and a bottom part of the middle portion of the section of the STI region is configured for filling of a dielectric layer.

In an embodiment, the dielectric layer is made of one or more dielectric materials.

In an embodiment, the STI region is made of one or more dielectric materials.

In an embodiment, the middle portion of the section of the STI region is hollowed through etching, corrosion or a sacrificial layer technology.

A multi-gate electronic device, comprising:
the multi-gate TID radiation-hardened device mentioned above.

In an embodiment, the multi-gate electronic device is a Fin Field-Effect Transistor (FinFET) device, a Gate-All-Around (GAA) device, or a Complementary Field-Effect Transistor (CFET) device.

Compared with the prior art, this application at least has the following beneficial effects.

This present disclosure provides a multi-gate TID radiation-hardened device. The middle portion of the STI region's cross-section is hollowed out, and the remaining STI region wraps around the Fin strips on both sides of the STI region. Due to the reduction in the size of the oxide layer, the number of radiation-induced oxide-trapped charges decreases, making it difficult for the Sub-Fin region to invert to form a leakage path. Therefore, the increase in the radiation-induced off-state leakage current can be relieved, thereby enhancing the TID radiation hardness. The hollowed STI region can reduce the number of radiation-induced trapped charges, thereby weakening the impact of TID radiation on the device performance.

Compared to traditional FinFET devices, the multi-gate TID radiation-hardened device provided herein has reduced parasitic capacitance.

Moreover, the multi-gate TID radiation-hardened device provided herein is fully compatible with the existing Complementary Metal Oxide Semiconductor (CMOS) process.

### BRIEF DESCRIPTION OF THE DRAWINGS

FIG. 1 schematically shows a STI region between two adjacent Fin structures in a multi-gate device according to an embodiment of the present disclosure;

FIG. 2a schematically illustrates the multi-gate device with the STI region partially removed in the Technology Computer Aided Design (TCAD) simulation;

FIG. 2b schematically illustrates the multi-gate device with a complete STI region in the TCAD simulation; and

FIG. 3 schematically illustrates a comparison between the multi-gate according to an embodiment of the present disclosure and the existing device in terms of the ratio of the off-state leakage current after irradiation (I_{off_irradiation}) to the off-state leakage current before irradiation I_{off_fresh}.

In the figures: 1—STI region; 2—gate structure; 3—Fin structure; and 4—semiconductor substrate.

### DETAILED DESCRIPTION OF EMBODIMENTS

The technical solutions in the embodiments of the present disclosure will be clearly and completely described below with reference to the accompanying drawings. Obviously, described below are merely some embodiments of the present disclosure rather than all embodiments. Based on the embodiments provided herein, all other embodiments obtained by those skilled in the art without making creative efforts shall fall within the scope of the present disclosure.

As used herein, the orientation or positional relationships indicated by terms “upper”, “low”, “top”, “bottom”, “inside”, and “outside”, etc. are based on those shown in the accompanying drawings. These terms are only for the purpose of facilitating and simplifying the description of the present disclosure, instead of indicating or implying that the device or element referred to must have a particular orientation, be constructed and operated in a particular orientation. Therefore, these terms should not be construed as limitations of the present disclosure. Furthermore, the terms “first”, “second”, etc. are used for descriptive purposes only, and are not to be understood as indicating or implying the relative importance.

In the present disclosure, unless otherwise expressly specified and limited, the terms “install”, “attach”, “connect”, “fix” and the like shall be interpreted in a broad sense. For example, it can be fixed connection, removable connection, or integral connection; mechanical connection or electrical connection; direct connection or indirect connection through an intermediate medium; or internal communication or interaction between two elements. For those skilled in the art, the specific meanings of the above terms in the present disclosure may be understood on a box-by-case basis.

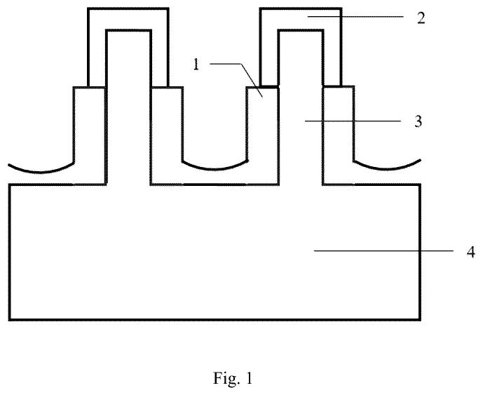

As shown in FIG. 1, the present disclosure provides a multi-gate total ionizing dose (TID) radiation-hardened device, including a semiconductor substrate 4 on which a shallow trench isolation (STI) region 1 and a plurality of Fin structures 3 are provided.

The STI region 1 is provided between adjacent two of the plurality of Fin structures 3. A middle portion of the section of the STI region 1 perpendicular to a source-drain direction is hollowed out. The middle portion of the section of the STI region 1 is configured to be partially or completely hollowed. The middle portion of the STI region 1 is configured to be completely hollowed out so as to expose the semiconductor substrate. The middle portion of the section of the STI region 1 is configured to be partially hollowed out and a bottom part of the section of the middle portion of the STI region 1 is configured to for filling with a dielectric layer. The dielectric material is preferably a single material selected from silicon dioxide, silicon nitride, silicon oxynitride, and aluminum oxide, or two or more of these materials.

A surface of an upper part of each of the plurality of Fin structures 3 not in contact with the STI region 1 is provided with the gate structure 2 across the plurality of Fin structure. A region of the plurality of Fin structures 3 in contact with the gate structure 2 is configured as a channel region.

A lower part of each of the plurality of Fin structures 3 is configured to be covered by the STI region 1. The source and the drain are provided at two ends of the channel region, respectively.

The STI region 1 is made of one or more dielectric materials. The dielectric material is preferably a single material selected from silicon dioxide, silicon nitride, silicon oxynitride, and aluminum oxide, or two or more of these materials.

The middle portion of the STI region 1 is hollowed out through etching, corrosion or a sacrificial layer technology.

On the other hand, the present disclosure also provides an application of the above-mentioned multi-gate TID radiation-hardened structure in multi-gate electronic devices, such as FinFET devices, GAA multi-gate devices and CFET devices.

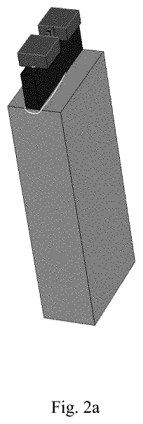

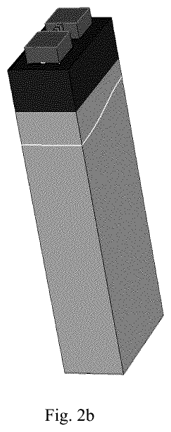

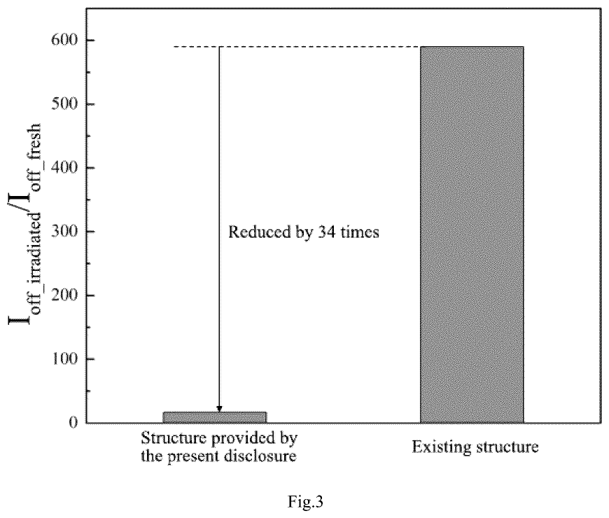

To verify the tolerance of the structure provided herein to the TID radiation, 3D simulations of bulk silicon-based FinFET devices were performed using a Sentaurus TCAD software. The device with the STI region 1 partially hollowed (i.e., the structure provided by the present application, as shown in FIG. 2a) is compared with the device with a complete STI region 1 (i.e., the existing structure, as shown in FIG. 2b) in terms of the off-state leakage current before and after TID radiation. As demonstrated by FIG. 3, the radiation induces a two-orders-of-magnitude increase in the off-state current (I_{off}) of the existing device, while the off-state current of the device provided herein only increases by one order of magnitude. Therefore, the structure provided herein exhibits stronger tolerance to the TID radiation.

In summary, compared to the existing structures, the multi-gate TID radiation-hardened structure provided by the present application shows a remarkably lower off-state leakage current under the exposure to the TID radiation (as shown in FIG. 3), indicating that its tolerance to TID radiation has been significantly enhanced.

It should be noted that the disclosed embodiments are merely exemplary, and are not limited to limit the present disclosure. Those skilled in the art can still make various changes, modifications and replacements to technical features recited in the above embodiments. It should be understood that those changes, modifications and replacements made without departing from the spirit of the disclosure shall fall within the scope of the disclosure defined by the appended claims.

What is claimed is:

1. A multi-gate total ionizing dose (TID) radiation-hardened device, comprising:
a semiconductor substrate;
wherein a plurality of Fin structures and a shallow trench isolation (STI) region are provided on the semiconductor substrate;
the STI region is provided between adjacent two of the plurality of Fin structures; and a middle portion of a section of the STI region perpendicular to a source-drain direction is configured to be hollowed out;
a surface of an upper part of each of the plurality of Fin structures not in contact with the STI region is provided with a gate structure across the plurality of Fin structures; and a region of the plurality of Fin structures in contact with the gate structure is configured as a channel region; and
a lower part of each of the plurality of Fin structures is configured to be covered by the STI region; and a source and a drain are provided at two ends of the channel region, respectively.

2. The multi-gate TID radiation-hardened device of claim 1, wherein the middle portion of the section of the STI region is configured to be partially or completely hollowed out.

3. The multi-gate TID radiation-hardened device of claim 2, wherein the middle portion of the section of the STI region is configured to be completely hollowed out to expose the semiconductor substrate.

4. The multi-gate TID radiation-hardened device of claim 2, wherein the middle portion of the section of the STI region is configured to be partially hollowed out, and a bottom part of the middle portion of the section of the STI region is configured for filling of a dielectric layer.

5. The multi-gate TID radiation-hardened device of claim 4, wherein the dielectric layer is made of one or more dielectric materials.

6. The multi-gate TID radiation-hardened device of claim 1, wherein the STI region is made of one or more dielectric materials.

7. The multi-gate TID radiation-hardened device of claim 1, wherein the middle portion of the section of the STI region is hollowed out through etching, corrosion or a sacrificial layer technology.

8. A multi-gate electronic device, comprising:
the multi-gate TID radiation-hardened device of claim 1.

9. The multi-gate electronic device of claim 8, wherein the multi-gate electronic device is a Fin Field-Effect Transistor (FinFET) device, a Gate-All-Around (GAA) device, or a Complementary Field-Effect Transistor (CFET) device.
